(19) United States
(12) Patent Application Publication
(10) Pub. No.: US 2020/0357770 A1
(43) Pub. Date: Nov. 12, 2020

(54) SEMICONDUCTOR PACKAGE AND MANUFACTURING METHOD THEREOF

(71) Applicant: Powertech Technology Inc., Hsinchu County (TW)

(72) Inventors: Chia-Wei Chiang, Hsinchu County (TW); Li-Chih Fang, Hsinchu County (TW); Wen-Jeng Fan, Hsinchu County (TW)

(73) Assignee: Powertech Technology Inc., Hsinchu County (TW)

(21) Appl. No.: 16/406,015

(22) Filed: May 8, 2019

(51) Int. Cl. H01L 25/065; H01L 23/00; H01L 23/31; H01L 23/528; H01L 23/522; H01L 21/56

(52) U.S. Cl. CPC H01L 25/0657; H01L 24/32; H01L 24/49; H01L 24/17; H01L 23/315; H01L 23/3128; H01L 2224/02373; H01L 23/5226; H01L 21/563; H01L 2224/0401; H01L 2224/0231; H01L 2224/02381; H01L 23/5283

(57) ABSTRACT

A semiconductor package and a manufacturing method thereof are provided. The semiconductor package includes a top semiconductor die, a bottom semiconductor die, a first encapsulant, a second encapsulant, a third encapsulant, a first redistribution layer and a second redistribution layer. The top semiconductor die is stacked on the bottom semiconductor die. The bottom semiconductor die is laterally encapsulated by the third encapsulant, and the third encapsulant is laterally surrounded by the first encapsulant. The top semiconductor die is laterally encapsulated by the second encapsulant. The first redistribution layer is disposed between the top and bottom semiconductor dies. The bottom semiconductor die, the first encapsulant and the third encapsulant are located between the first and second redistribution layers.

### BACKGROUND

### Technical Field

The present disclosure relates to a semiconductor package and a manufacturing method thereof.

### Description of Related Art

In recent decades, the semiconductor industry has experienced rapid growth due to continuous improvements in integration density of circuits in semiconductor dies. For the most part, this improvement in integration density has come from successive reductions in minimum feature size, which allows more components to be integrated into a given area. As the demand for even smaller electronic devices has grown recently, there has grown a need for smaller and more creative packaging techniques of semiconductor dies.

### SUMMARY

A semiconductor package according to some embodiments of the present disclosure includes a top semiconductor die, a bottom semiconductor die, a first encapsulant, a second encapsulant, a third encapsulant, a first redistribution layer and a second redistribution layer. The top semiconductor die is stacked on the bottom semiconductor die. The bottom semiconductor die is laterally surrounded by the first encapsulant. The top semiconductor die is laterally encapsulated by the second encapsulant. The bottom semiconductor die is laterally encapsulated by the third encapsulant, and the third encapsulant is laterally surrounded by the first encapsulant. The first redistribution layer is disposed between the top semiconductor die and the bottom semiconductor die, and electrically connected with the top semiconductor die. The bottom semiconductor die, the first encapsulant and the third encapsulant are located between the first redistribution layer and the second redistribution layer. The second redistribution layer is electrically connected with the first redistribution layer and the bottom semiconductor die.

In some embodiments, the top semiconductor die has an active side at which a plurality of conductive pillars are located and a back side opposite to the active side. The active side of the top semiconductor die faces toward the first redistribution layer, and the back side of the top semiconductor die faces away from the first redistribution layer.

In some embodiments, the top semiconductor die has an active side and a back side opposite to the active side. The back side of the top semiconductor die faces toward the first redistribution layer. The active side of the top semiconductor die faces away from the first redistribution layer, and electrically connected to the first redistribution layer via a plurality of bonding wires.

In some embodiments, the bottom semiconductor die has an active side at which a plurality of conductive pillars are located and a back side opposite to the active side. The active side of the bottom semiconductor die faces toward the second redistribution layer, and the back side of the bottom semiconductor die faces toward the first redistribution layer.

In some embodiments, the semiconductor package further includes a die attach film. The die attach film is disposed between the back side of the bottom semiconductor die and the first redistribution layer.

In some embodiments, an interface exists between the first encapsulant and the third encapsulant.

In some embodiments, a thermal conductivity of the third encapsulant is greater than a thermal conductivity of the first encapsulant and a thermal conductivity of the second encapsulant.

In some embodiments, a Young's modulus of the third encapsulant is greater than a Young's modulus of the first encapsulant and a Young's modulus of the second encapsulant.

In some embodiments, substantially the whole sidewall of the third encapsulant is covered by the first encapsulant.

In some embodiments, the first redistribution layer and the second redistribution layer are electrically connected with each other by a through encapsulant via penetrating through the first encapsulant.

In some embodiments, the semiconductor package further includes a plurality of electrical connectors. The plurality of electrical connectors are disposed at a surface of the second redistribution layer that is facing away from the first redistribution layer.

A manufacturing method of a semiconductor package according to some embodiments in the present disclosure includes: forming a sacrificial pattern over a first carrier; laterally encapsulating the sacrificial pattern by a first encapsulant; forming a first redistribution layer over the sacrificial pattern and the first encapsulant; attaching a first semiconductor die over the first redistribution layer; laterally encapsulating the first semiconductor die by a second encapsulant; attaching a second carrier to the second encapsulant; detaching the first carrier from the sacrificial pattern and the first encapsulant; removing the sacrificial pattern to expose a portion of the first redistribution layer; attaching a second semiconductor die to the exposed portion of the first redistribution layer; laterally encapsulating the second semiconductor die by a third encapsulant; forming a second redistribution layer over the first encapsulant and the third encapsulant; and detaching the second carrier.

In some embodiments, the first semiconductor die is attached onto the first redistribution layer via a flip-chip process.

In some embodiments, the first semiconductor die is attached onto the first redistribution layer via a wire bonding process.

In some embodiments, the second semiconductor die is attached to the first redistribution layer via a die attach film.

In some embodiments, the manufacturing method of the semiconductor package further includes: forming a through encapsulant via penetrating through the first encapsulant.

In some embodiments, the step of forming the through encapsulant via follows the step of detaching the first carrier, and precedes the step of removing the sacrificial pattern.

In some embodiments, the step of forming the through encapsulant via precedes the step of forming the first redistribution layer.

In some embodiments, the manufacturing method of the semiconductor package further includes: forming a plurality of electrical connectors at a side of the second redistribution layer facing away from the first redistribution layer.

In some embodiments, the sacrificial pattern comprises a photosensitive material.

As above, the semiconductor package of some embodiments in the present disclosure is a three dimensional package structure. The semiconductor package includes a bottom semiconductor die (also referred as the second semiconductor die) and a top semiconductor die (also referred as the first semiconductor die) stacked on the bottom semiconductor die. The top and bottom semiconductor dies are respectively encapsulated by an encapsulant (i.e., the second encapsulant and the third encapsulant), and the encapsulant encapsulating the bottom semiconductor die (i.e., the third encapsulant) is laterally surrounded by another encapsulant (i.e., the first encapsulant). Moreover, the semiconductor package includes at least one redistribution layer (e.g., the first redistribution layer and the second redistribution layer) for out-routing the top and bottom semiconductor dies as well as realizing communication between the top and bottom semiconductor dies. During manufacturing of the semiconductor package, landing region of the bottom semiconductor die is confined in a space, which is once occupied by the sacrificial pattern and surrounded by the first encapsulant. Therefore, misalignment of the bottom semiconductor die during attachment of the bottom semiconductor die as well as offset of the attached bottom semiconductor die due to inevitable heat in the subsequent manufacturing process can be reduced. Accordingly, process yield of the manufacturing of the semiconductor package can be improved.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a flow chart illustrating a manufacturing method of a semiconductor package according to some embodiments of the present disclosure.

FIG. 2A through FIG. 2K are cross-sectional views illustrating structures at various stages of the manufacturing method of the semiconductor package shown in FIG. 1.

### DESCRIPTION OF THE EMBODIMENTS

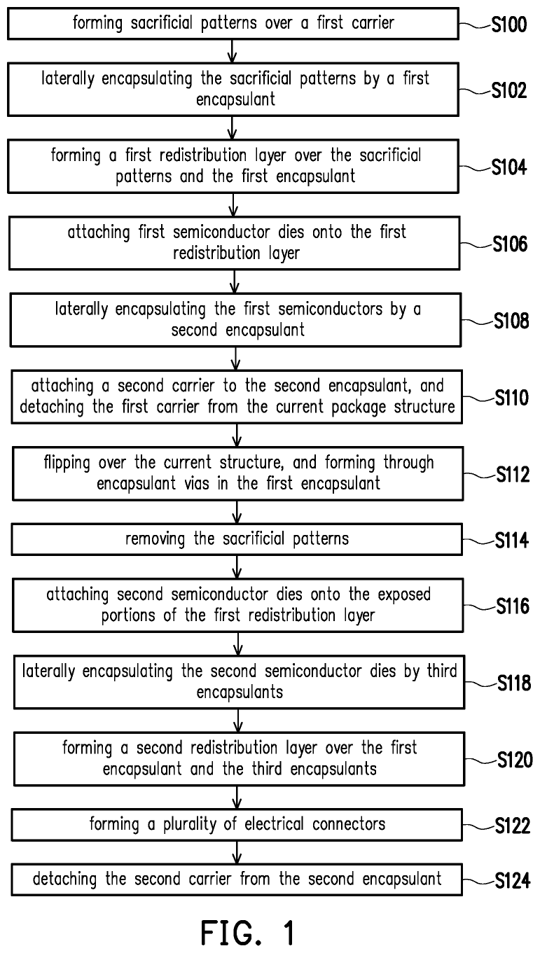

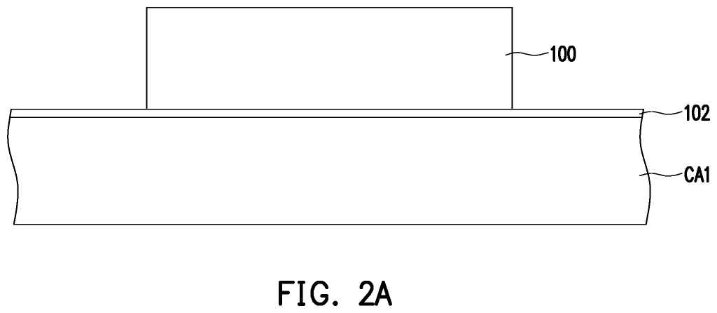

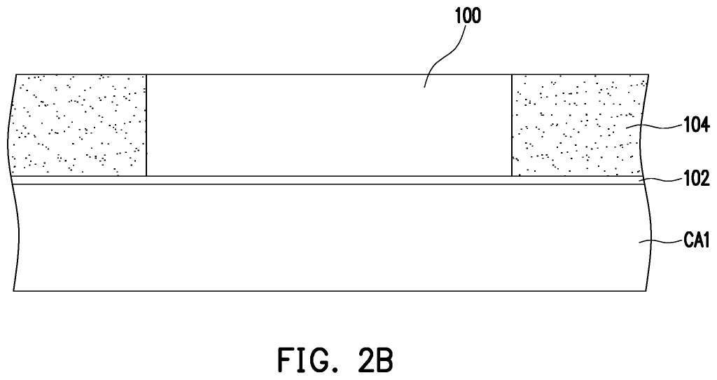

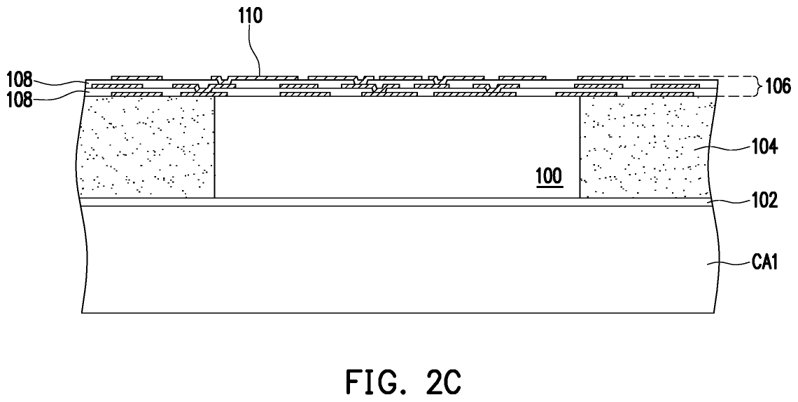

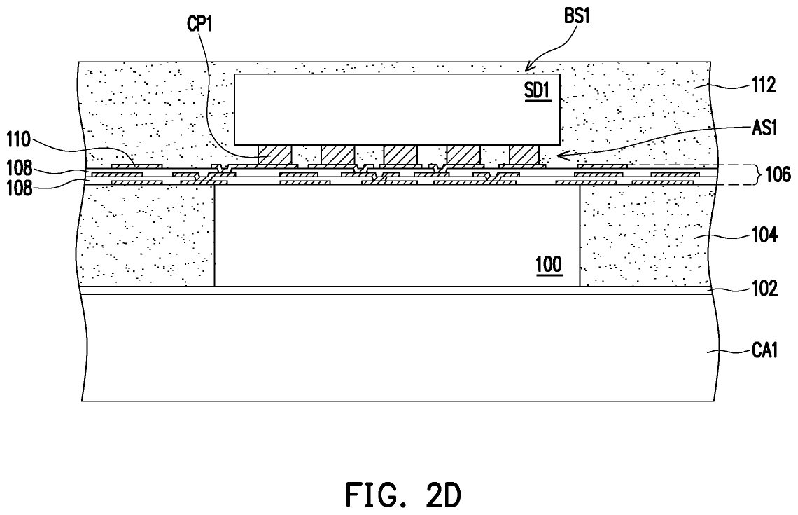

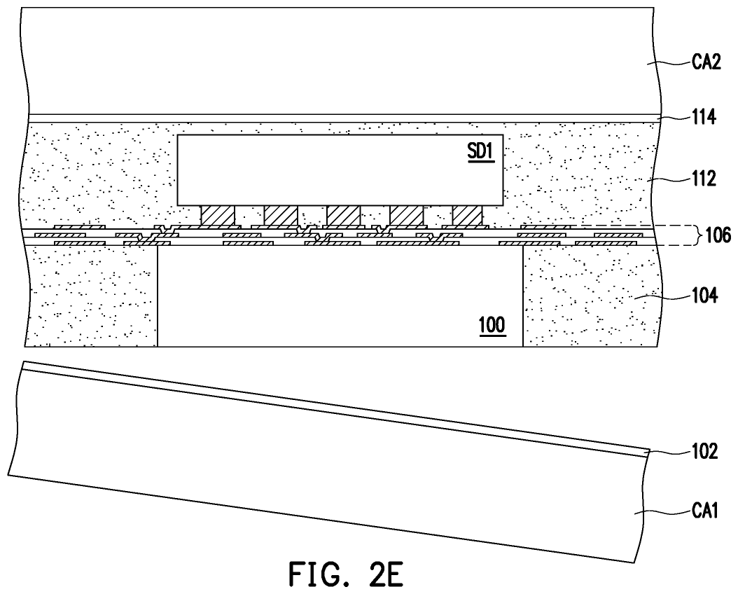

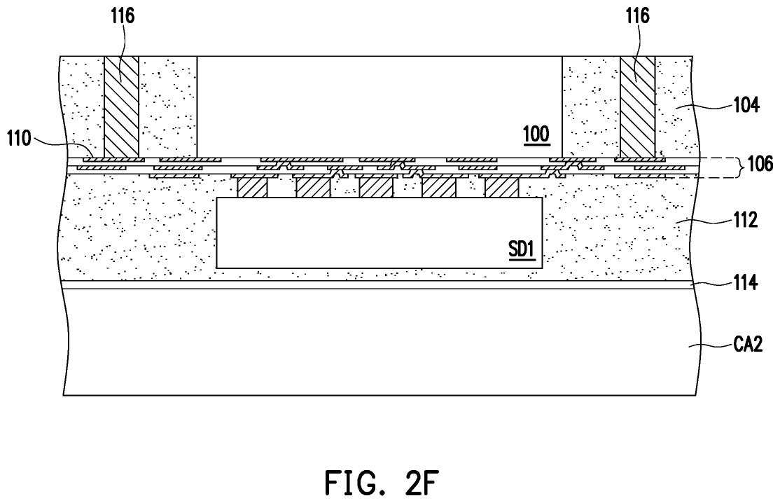

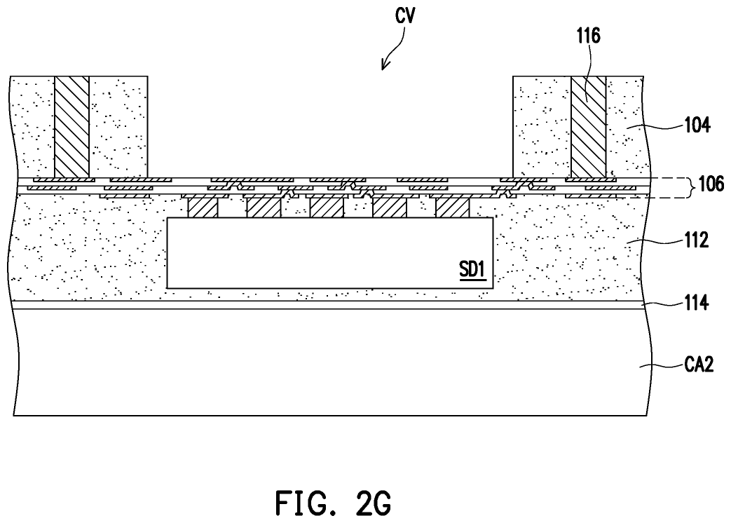

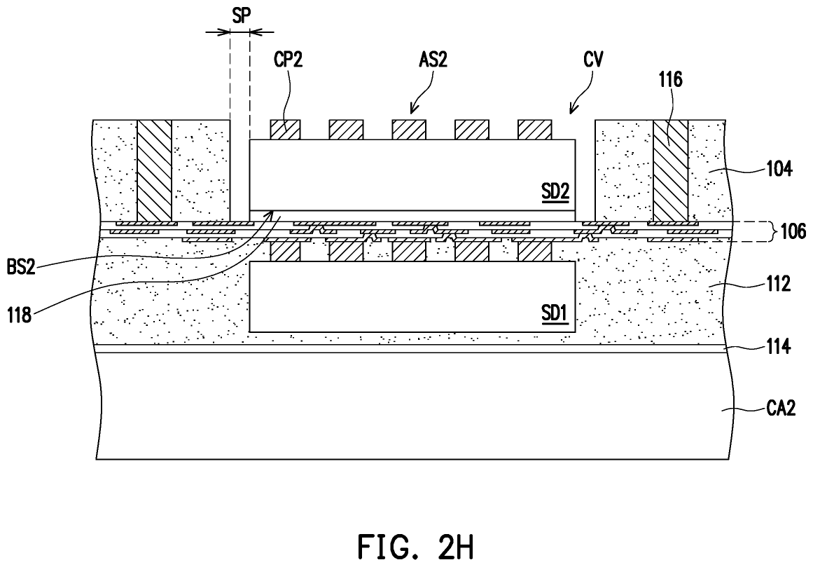

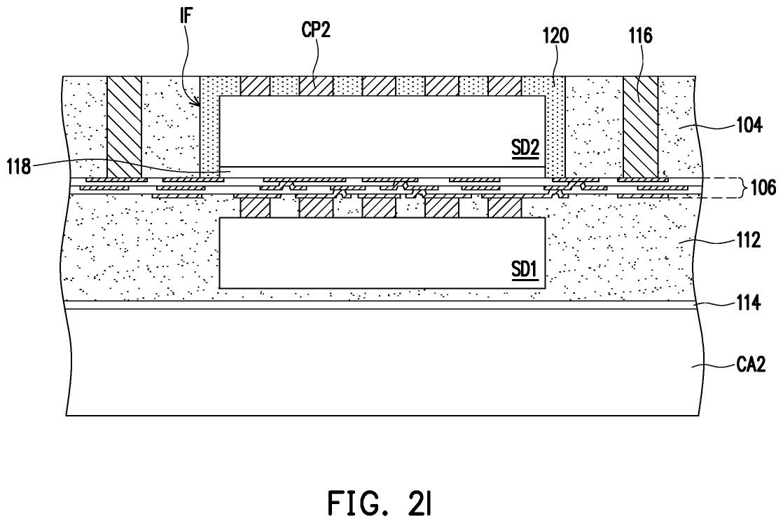

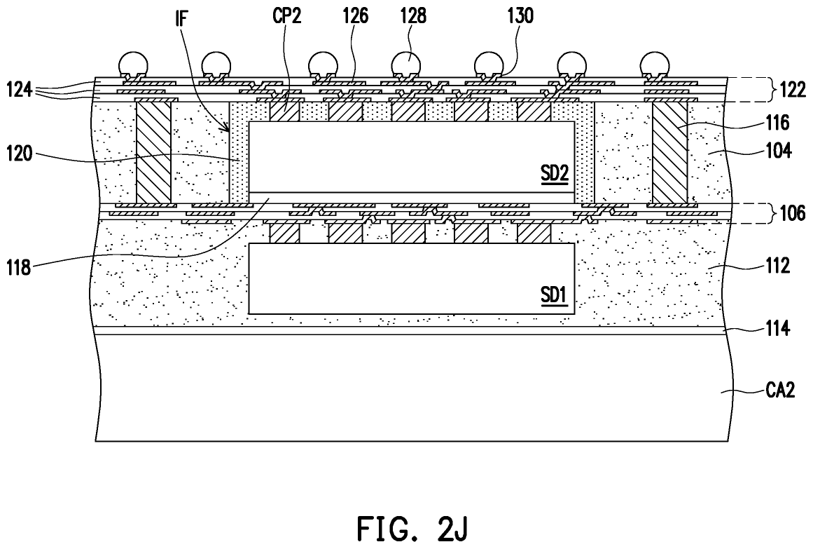

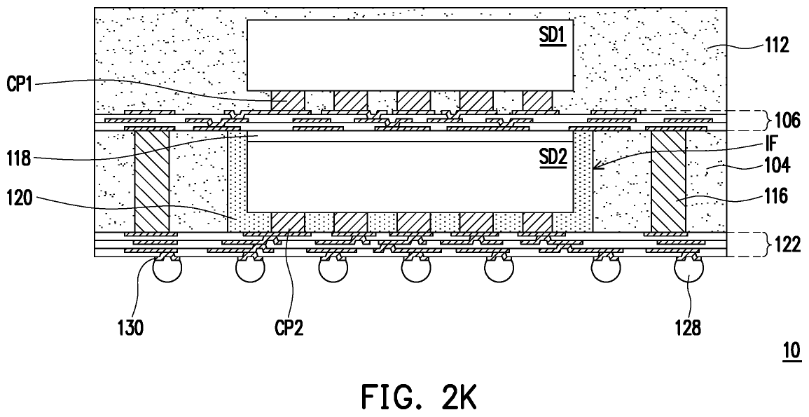

FIG. 1 is a flow chart illustrating a manufacturing method of a semiconductor package according to some embodiments of the present disclosure. FIG. 2A through FIG. 2K are cross-sectional views illustrating structures at various stages of the manufacturing method of the semiconductor package shown in FIG. 1.

Referring to FIG. 1 and FIG. 2A, step S100 is performed, and sacrificial patterns 100 are formed over a first carrier CAL The first carrier CA1 is, for example, a glass substrate. In some embodiments, an adhesion layer 102 is pre-formed over a surface of the first carrier CA1, on which the sacrificial patterns 100 are subsequently formed. The adhesion layer 102 is, for example, a light-to-heat conversion (LTHC) layer or a thermal release layer. Even though merely a single sacrificial pattern 100 is depicted in FIG. 2A, multiple sacrificial patterns 100 may actually be formed over the first carrier CAL The sacrificial patterns 100 are laterally separated with one another. An area of each sacrificial pattern 100 may be greater than an area of a semiconductor die (e.g., the second semiconductor die SD2 shown in FIG. 2H), such that the semiconductor die can be accommodated in the space (e.g., the cavity CV as shown in FIG. 2H) once occupied by the sacrificial pattern 100. For instance, the area of each sacrificial pattern 100 may range from 50 mm² to 225 mm². A method for forming the sacrificial patterns 100 may include forming a blanket material layer (not shown) over the first carrier CA1, then patterning the blanket material layer to form the sacrificial patterns 100. In some embodiments, a material of the blanket material layer for forming the sacrificial patterns 100 is a photosensitive material, such as a positive type photoresist or a negative type photoresist. In these embodiments, the pattering process performed on the blanket material may be a photolithography process.

Referring to FIG. 1 and FIG. 2B, step S102 is performed, and the sacrificial patterns 100 are laterally encapsulated by a first encapsulant 104. In some embodiments, the sacrificial patterns 100 may be initially over-molded by an encapsulating material, and then a planarization process may be performed on the encapsulating material to expose the sacrificial patterns 100 and form the first encapsulant 104. For instance, a material of the first encapsulant 104 may include epoxy resin, polyimide, silica, the like or a combination thereof. In addition, the planarization process may include a chemical mechanical polishing (CMP) process, an etching process, a grinding process or a combination thereof. In some embodiments, as shown in FIG. 2B, a surface of the first encapsulant 104 facing away from the first carrier CA1 is substantially coplanar with exposed surfaces of the sacrificial patterns 100.

Referring to FIG. 1 and FIG. 2C, step S104 is performed, and a first redistribution layer 106 is formed over the sacrificial patterns 100 and the first encapsulant 104. In some embodiments, the first redistribution layer 106 includes a stack of insulating layers 108, as well as redistribution elements 110 formed in the stack of the insulating layers 108. The redistribution elements 110 are distributed to substantially the whole range of the insulating layers 108, and are overlapped with the sacrificial patterns 100 and the first encapsulant 104. The redistribution elements 110 may respectively be a conductive trace, a conductive via or a combination thereof. The conductive trace extends along one or more directions substantially parallel to an extending direction of the insulating layer 108, whereas the conductive via penetrates at least one of the insulating layers 108 and electrically connected to one of the conductive traces. In some embodiments, a material of the insulating layers 108 includes a polymer material, and a material of the redistribution elements 110 includes a metal or a metal alloy. For instance, the polymer material includes polyimide, polybenzoxazole (PBO), benzocyclobutene (BCB), the like or a combination thereof, and the metal/metal alloy includes copper, nickel, titanium, the like or a combination thereof. In alternative embodiments, the insulating layers 108 are inorganic insulating layers, and are made of, for example, silicon oxide, silicon nitride or the like.

Referring to FIG. 1 and FIG. 2D, step S106 is performed, and first semiconductor dies SD1 are attached onto the first redistribution layer 106. Even though merely a single first semiconductor die SD1 is depicted in FIG. 2D, multiple first semiconductor dies SD1 may actually be attached onto the first redistribution layer 106. The attached first semiconductor dies SD1 are laterally separated, and respectively overlapped with the sacrificial patterns 100. In certain embodiments, the first semiconductor dies SD1 may be respectively located within a range of the underlying sacrificial pattern 100. However, those skilled in the art may modify a configuration of the sacrificial patterns 100 and the first semiconductor dies SD1, the present disclosure is not limited thereto. In some embodiments, the first semiconductor dies SD1 may respectively be a logic integrated circuit (IC) die, a memory IC die, an analog IC die, an application-specific IC (ASIC) die, or the like. Each of the first semiconductor dies SD1 has an active side AS1 at which a plurality of conductive pillars CP1 are located, and has a back side BS1 opposite to the active side AS1. In some embodiments, the first semiconductor dies SD1 are attached onto the first redistribution layer 106 via a flip-chip bonding process. In these embodiments, the conductive pillars CP1 are in contact and electrically connected with the topmost redistribution elements 110 of the first redistribution layer 106. In other words, the active sides AS1 of the first semiconductor dies SD1 face toward the first redistribution layer 106, whereas back sides BS1 of the first semiconductor dies SD1 face away from the first redistribution layer 106. In alternative embodiments, the first semiconductor dies SD1 may be attached onto the first redistribution layer 106 via a wire bonding process. In these alternative embodiments, the active sides AS1 of the first semiconductor dies SD1 face away from the first redistribution layer 106 and electrically connected to the first redistribution layer 106 via a plurality of bonding wires (not shown), whereas the back sides BS1 of the first semiconductor dies SD1 face toward the first redistribution layer 106. Moreover, in these alternative embodiments, each of the first semiconductor dies SD1 may be replaced by a stack of semiconductor dies (not shown).

Thereafter, step S108 is performed, and the first semiconductor dies SD1 are laterally encapsulated by a second encapsulant 112. In some embodiments, the first semiconductor dies SD1 are over-molded by the second encapsulant 112, and are buried in the second encapsulant 112. A material of the second encapsulant 112 may include epoxy resin, polyimide, silica, the like or a combination thereof. Up to here, the current package structure includes a stack of two encapsulants (i.e., the first encapsulant 104 and the second encapsulant 112), which are vertically separated from each other by the first redistribution layer 106.

Referring to FIG. 1, FIG. 2D and FIG. 2E, step S110 is performed, such that a second carrier CA2 is attached to the second encapsulant 112, and the first carrier CA1 is detached from the current package structure. The second carrier CA2 is attached onto a surface of the second encapsulant 112 facing away from the first redistribution layer 106. In some embodiments, an adhesion layer 114 is pre-formed on a surface of the second carrier CA2 at which the second encapsulant 112 to be attached. The adhesion layer 114 is, for example, a light-to-heat conversion (LTHC) layer or a thermal release layer. On the other side, in those embodiments where the adhesion layer 102 formed on the first carrier CA1 is a LTHC release layer or a thermal release layer, the first carrier CA1 is detached from the current package structure as the adhesion layer 102 lose its adhesive property when exposed to light or heat. After detaching the first carrier CA1, surfaces of the first encapsulant 104 and the sacrificial patterns 100 facing away from the first redistribution layer 106 are currently exposed.

Referring to FIG. 1, FIG. 2E and FIG. 2F, step S112 is performed, such that the structure shown in FIG. 2E is flipped over, and through encapsulant vias 116 are formed in the first encapsulant 104. The through encapsulant vias 116 penetrate through the first encapsulant 104, and are electrically connected with the redistribution elements 110 in the first redistribution layer 106. In some embodiments, a method for forming the through encapsulant vias 116 includes removing portions of the first encapsulant 104 to form through holes in the first encapsulant 104 by, for example, a mechanical drilling process or a laser drilling process. Subsequently, a conductive material is filled into the through holes of the first encapsulant 104 to form the through encapsulant vias 116. For instance, the conductive material may include copper, titanium, aluminum, nickel, the like or a combination thereof. In some embodiments, the conductive material may initially extend onto the exposed surfaces of the first encapsulant 104 and the sacrificial patterns 100, and then a planarization process may be performed on the conductive material to remove a portion of the conductive material above the exposed surfaces of the first encapsulant 104 and the sacrificial patterns 100, so as to form the through encapsulant vias 116. For instance, the planarization process may include a CMP process, an etching process, a grinding process or a combination thereof. In some embodiments, exposed surfaces of the through encapsulant vias 116 are substantially coplanar with the exposed surfaces of the first encapsulant 104 and the sacrificial patterns 100.

According to the afore-described embodiments, the step of forming the through encapsulant vias 116 is performed after the steps of forming the first redistribution layer 106 and attaching the first semiconductor dies SD1. However, in alternative embodiments, the step of forming the through encapsulant vias 116 may be performed before the steps of forming the first redistribution layer 106 and attaching the first semiconductor dies SD1. In these alternative embodiments, the step of forming the through encapsulant vias 116 may be performed after the step of laterally encapsulating the sacrificial patterns 100 by the first encapsulant 104 (as shown in FIG. 2B), and before the step of forming the first redistribution layer 106 (as shown in FIG. 2C).

Referring to FIG. 1, FIG. 2F and FIG. 2G, step S114 is performed, and the sacrificial patterns 100 are removed. In some embodiments, the sacrificial patterns 100 are removed by a stripping process or an etching process. Once the sacrificial patterns 100 are removed, cavities CV are formed in the first encapsulant 104, and some portions of the first redistribution layer 106 are exposed by the cavities CV. As shown in FIG. 2F and FIG. 2G, the cavities CV are spaces used to be occupied by the sacrificial patterns 100. As with the sacrificial patterns 100, the cavities CV are respectively overlapped with the first semiconductor dies SD1. In addition, in certain embodiments, each of the first semiconductor dies SD1 is located within a range of the overlying cavity CV.

Referring to FIG. 1, FIG. 2G and FIG. 2H, step S116 is performed, and second semiconductor dies SD2 are respectively attached onto the exposed portions of the first redistribution layer 106. The attached second semiconductor dies SD2 are respectively located in the cavities CV, and are overlapped with the first semiconductor dies SD1. In some embodiments, a spacing SP between a boundary of each cavity CV and the corresponding second semiconductor die SD2 may range from 25 μm to 30 μm. In addition, the second semiconductor dies SD2 located in the cavities CV of the first encapsulant 104 and the first semiconductor dies SD1 embedded in the second encapsulant 112 may be the same type of semiconductor dies, or may be different types of semiconductor dies. In some embodiments, the second semiconductor dies SD2 are respectively a logic integrated circuit (IC) die, a memory IC die, an analog IC die, an application-specific IC (ASIC) die, or the like. Each of the second semiconductor dies SD2 has an active side AS2 at which a plurality of conductive pillars CP2 are located, and has a back side BS2 opposite to the active side AS2. Back sides BS2 of the second semiconductor dies SD2 face toward the first redistribution layer 106, whereas active sides AS2 of the second semiconductor dies SD2 face away from the first redistribution layer 106. In some embodiments, the back side BS2 of each second semiconductor die SD2 may be attached to the first redistribution layer 106 via a die attach film (DAF) 118. In these embodiments, the DAFs 118 may be pre-formed at the back sides BS of the second semiconductor dies SD2 before the second semiconductor dies SD2 are attached onto the first redistribution layer 106. Alternatively, the DAFs 118 may be pre-formed at the exposed portions of the first redistribution layer 106 before the second semiconductor dies SD2 are attached onto the first redistribution layer 106.

Referring to FIG. 1 and FIG. 21, step S118 is performed, and each of the second semiconductor dies SD2 is laterally encapsulated by a third encapsulant 120. Each of the third encapsulant 120 can be regarded as being surrounded by the first encapsulant 104, and the first encapsulant 104 as well as the third encapsulants 120 are vertically separated from the underlying second encapsulant 112 by the first redistribution layer 106. In some embodiments, substantially the whole sidewall of each third encapsulant 120 is covered by the first encapsulant 104. A method for forming the third encapsulants 120 may include filling an encapsulating material into the cavities CV (as shown in FIG. 2H) of the first encapsulant 104. The encapsulating material may fill up the cavities CV, and extends onto surfaces of the first encapsulant 104 and the through encapsulant vias 116. Subsequently, a planarization process may be performed on the encapsulating material, and portions of the encapsulating material above the surfaces of the first encapsulant 104 and the through encapsulant vias 116 are removed, so as to form the third encapsulants 120. For instance, the planarization process may include a CMP process, an etching process, a grinding process or a combination thereof. In some embodiments, exposed surfaces of the third encapsulants 120 are substantially coplanar with the exposed surfaces of the first encapsulant 104, the through encapsulant vias 116 and the conductive pillars CP2 of the second semiconductor dies SD2.

In some embodiments, a material of the third encapsulants 120 is different from the material(s) of the first encapsulant 104 and the second encapsulant 112. In these embodiments, a thermal conductivity of the third encapsulants 120 may be greater than a thermal conductivity of the first encapsulant 104 and a thermal conductivity of the second encapsulant 112, and heat dissipation of the second semiconductor dies SD2 embedded in the third encapsulants 120 can be improved. For instance, the thermal conductivity of the third encapsulants 120 may be up to 3 W/mK, whereas the thermal conductivity of the first encapsulant 104 and the thermal conductivity of the second encapsulant 112 may be respectively up to 0.7 W/mK. Besides, in these embodiments, a Young's modulus of the third encapsulants 120 may be greater than a Young's modulus of the first encapsulant 104 and a Young's modulus of the second encapsulant 112, and mechanical protection for the second semiconductor dies SD2 embedded in the third encapsulants 120 can be improved. For instance, the Young's modulus of the third encapsulants 120 may be up to 30 GPa, whereas the Young's modulus of the first encapsulant 104 and the Young's modulus of the second encapsulant 112 may respectively be up to 15 GPa.

In alternative embodiments, the material of the third encapsulant 120 is the same as the material of the first encapsulant 104 and/or the material of the second encapsulant 112. It should be noted that, even the first encapsulant 104 and the third encapsulants 120 are made of the same material, interfaces IF between the first encapsulant 104 and the third encapsulants 120 can still be observed because the first encapsulant 104 and the third encapsulants 120 are formed at different steps.

Referring to FIG. 1, FIG. 21 and FIG. 2J, step S120 is performed, and a second redistribution layer 122 is formed over the first encapsulant 104 and the third encapsulants 120. In some embodiments, the second redistribution layer 122 is globally formed over the package structure shown in FIG. 21. As such, the surfaces of the first encapsulant 104, the through encapsulant vias 116, the third encapsulants 120 and the conductive pillars CP2 of the second semiconductor dies SD2 are covered by the second redistribution layer 122. The second redistribution layer 122 is electrically connected with the through encapsulant vias 116 and the conductive pillars CP2 of the second semiconductor dies SD2. As such, out-routing of the first semiconductor dies SD1 and the second semiconductor dies SD2 as well as communication between the first semiconductor die SD1 and the second semiconductor die SD2 may be realized by the first redistribution layer 106, the through encapsulant vias 116 and the second redistribution layer 122. In some embodiments, the second redistribution layer 122 includes a stack of insulating layers 124 and a plurality of redistribution elements 126 formed in the stack of insulating layers 124. The redistribution elements 126 are electrically connected with the through encapsulant vias 116 and the conductive pillars CP2 of the second semiconductor dies SD2, and fan out from the through encapsulant vias 116 and the conductive pillars CP2 to substantially the whole area of the insulating layers 124. In some embodiments, the redistribution elements 126 respectively are a conductive trace, a conductive via or a combination thereof. The conductive trace extends along one or more directions substantially parallel to an extending direction of the insulating layer 124, whereas the conductive via penetrates at least one of the insulating layers 124 and electrically connected to one of the conductive traces. In some embodiments, a material of the insulating layers 124 includes a polymer material, and a material of the redistribution elements 126 includes a metal or a metal alloy. For instance, the polymer material includes polyimide, polybenzoxazole (PBO), benzocyclobutene (BCB), the like or a combination thereof, and the metal/metal alloy includes copper, nickel, titanium, the like or a combination thereof. In alternative embodiments, the insulating layers 124 are inorganic insulating layers, and are made of, for example, silicon oxide, silicon nitride or the like.

Thereafter, step S122 is performed, and a plurality of electrical connectors 128 are formed. The electrical connectors 128 are formed over the current package structure, and may extend into the topmost insulating layer 124 of the second redistribution layer 122, so as to electrically connect with the redistribution elements 126 of the second redistribution layer 122. A method for forming the electrical connectors 128 may include removing some portions of the topmost insulating layer 124 to form openings exposing some portions of the redistribution elements 126. Subsequently, the electrical connectors 128 are respectively disposed over the exposed portions of the redistribution elements 126. In some embodiments, under ball metallization (UBM) layers 130 are respectively formed in the openings of the topmost insulating layer 124 before the electrical connectors 128 are disposed. As such, after disposing the electrical connectors 128, the UBM layers 130 are respectively located between the electrical connectors 128 and the second redistribution layer 122. In some embodiments, the UBM layers 130 further extend onto a surface of the topmost insulating layer 124 outside the afore-mentioned openings. The electrical connectors 128 may include micro-bumps, controlled collapse chip connection (C4) bumps, ball grid array (BGA) balls, solder balls or the like. In addition, a material of the UBM layer 130 may include Cr, Cu, Ti, W, Ni, Al, the like or combinations thereof.

Referring to FIG. 1, FIG. 2J and FIG. 2K, step S124 is performed, and the second carrier CA2 is detached from the second encapsulant 112. In those embodiments where the adhesion layer 114 formed on the second carrier CA2 is a LTHC release layer or a thermal release layer, the second carrier CA2 is detached from the current package structure as the adhesion layer 114 lose its adhesive property when exposed to light or heat. After detaching the second carrier CA2, a surface of the second encapsulant 112 facing away from the first redistribution layer 106 is currently exposed. In addition, the current package structure is flipped over, as shown in FIG. 2K. In some embodiments, the current package structure is subjected to a singulation process, such as a dicing process, a sawing process or a laser ablation process. The package structure may be attached onto a tape or another carrier (not shown) during the singulation process, and such tape or carrier is removed after the singulation step. The singulated package structure, as shown in FIG. 2K, is referred as a semiconductor package 10. The semiconductor package 10 includes a stack of semiconductor dies (i.e., the first semiconductor die SD1 and the second semiconductor die SD2) each encapsulated by at least a encapsulant (i.e., the first encapsulant 104, the second encapsulant 112 and the third encapsulant 120), and includes at least a redistribution layer (e.g., the first redistribution layer 106 and the second redistribution layer 122) functioned for out-routing the semiconductor dies and realizing communication between the semiconductor dies. Accordingly, the semiconductor package 10 may be regarded as a three dimensional package structure, such as a fan-out package-on-package (PoP) structure. In some embodiments, as a result of the singulation process, a sidewall of the first encapsulant 104 is substantially coplanar with a sidewall of the second encapsulant 112.

In the embodiments described above, the step of forming the electrical connectors 128, the step of detaching the second carrier CA2 and the step of singulation are sequentially performed. The present disclosure is not limited to a sequence in which these steps are performed.

As above, the semiconductor package 10 of some embodiments in the present disclosure is a three dimensional package structure. The semiconductor package 10 includes a bottom semiconductor die (i.e., the second semiconductor die SD2) and a top semiconductor die (i.e., the first semiconductor die SD1) stacked on the bottom semiconductor die. The top and bottom semiconductor dies are respectively encapsulated by an encapsulant (i.e., the second encapsulant 112 and the third encapsulant 120), and the encapsulant encapsulating the bottom semiconductor die (i.e., the third encapsulant 120) is laterally surrounded by another encapsulant (i.e., the first encapsulant 104). Moreover, the semiconductor package 10 includes at least one redistribution layer (e.g., the first redistribution layer 106 and the second redistribution layer 122) for out-routing the top and bottom semiconductor dies as well as realizing communication between the top and bottom semiconductor dies. During manufacturing of the semiconductor package 10, landing region of the bottom semiconductor die is confined in the cavity (i.e., the cavity CV shown in FIG. 2H) defined by the surrounding first encapsulant 104. Therefore, misalignment of the bottom semiconductor die during attachment of the bottom semiconductor die as well as offset of the attached bottom semiconductor die due to inevitable heat in the manufacturing process can be reduced. Accordingly, process yield of the manufacturing of the semiconductor package 10 can be improved.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

1. A semiconductor package, comprising:
a top semiconductor die and a bottom semiconductor die, wherein the top semiconductor die is stacked on the bottom semiconductor die;
a first encapsulant, laterally surrounding the bottom semiconductor die;
a second encapsulant, laterally encapsulating the top semiconductor die;
a third encapsulant, laterally encapsulating the bottom semiconductor die, and laterally surrounded by the first encapsulant;
a first redistribution layer, disposed between the top semiconductor die and the bottom semiconductor die, and electrically connected with the top semiconductor die; and
a second redistribution layer, wherein the bottom semiconductor die, the first encapsulant and the third encapsulant are located between the first redistribution layer and the second redistribution layer, and wherein the second redistribution layer is electrically connected with the first redistribution layer and the bottom semiconductor die.

2. The semiconductor package according to claim 1, wherein the top semiconductor die has an active side at which a plurality of conductive pillars are located and a back side opposite to the active side, the active side of the top semiconductor die faces toward the first redistribution layer, and the back side of the top semiconductor die faces away from the first redistribution layer.

3. The semiconductor package according to claim 1, wherein the top semiconductor die has an active side and a back side opposite to the active side, the back side of the top semiconductor die faces toward the first redistribution layer, and the active side of the top semiconductor die faces away from the first redistribution layer, and electrically connected to the first redistribution layer via a plurality of bonding wires.

4. The semiconductor package according to claim 1, wherein the bottom semiconductor die has an active side at which a plurality of conductive pillars are located and a back side opposite to the active side, the active side of the bottom semiconductor die faces toward the second redistribution layer, and the back side of the bottom semiconductor die faces toward the first redistribution layer.

5. The semiconductor package according to claim 4, further comprising a die attach film, wherein the die attach film is disposed between the back side of the bottom semiconductor die and the first redistribution layer.

6. The semiconductor package according to claim 1, wherein an interface exists between the first encapsulant and the third encapsulant.

7. The semiconductor package according to claim 1, wherein a thermal conductivity of the third encapsulant is greater than a thermal conductivity of the first encapsulant and a thermal conductivity of the second encapsulant.

8. The semiconductor package according to claim 1, wherein a Young's modulus of the third encapsulant is greater than a Young's modulus of the first encapsulant and a Young's modulus of the second encapsulant.

9. The semiconductor package according to claim 1, wherein substantially the whole sidewall of the third encapsulant is covered by the first encapsulant.

10. The semiconductor package according to claim 1, wherein the first redistribution layer and the second redistribution layer are electrically connected with each other by a through encapsulant via penetrating through the first encapsulant.

11. The semiconductor package according to claim 1, further comprising a plurality of electrical connectors, wherein the plurality of electrical connectors are disposed at a surface of the second redistribution layer that is facing away from the first redistribution layer.

12. A manufacturing method of a semiconductor package, comprising:
forming a sacrificial pattern over a first carrier;
laterally encapsulating the sacrificial pattern by a first encapsulant;
forming a first redistribution layer over the sacrificial pattern and the first encapsulant;
attaching a first semiconductor die over the first redistribution layer;
laterally encapsulating the first semiconductor die by a second encapsulant;
attaching a second carrier to the second encapsulant;
detaching the first carrier from the sacrificial pattern and the first encapsulant;
removing the sacrificial pattern to expose a portion of the first redistribution layer;
attaching a second semiconductor die to the exposed portion of the first redistribution layer;
laterally encapsulating the second semiconductor die by a third encapsulant;
forming a second redistribution layer over the first encapsulant and the third encapsulant; and
detaching the second carrier.

13. The manufacturing method of the semiconductor package according to claim 12, wherein the first semiconductor die is attached onto the first redistribution layer via a flip-chip process.

14. The manufacturing method of the semiconductor package according to claim 12, wherein the first semiconductor die is attached onto the first redistribution layer via a wire bonding process.

15. The manufacturing method of the semiconductor package according to claim 12, wherein the second semiconductor die is attached to the first redistribution layer via a die attach film.

16. The manufacturing method of the semiconductor package according to claim 12, further comprising:
forming a through encapsulant via penetrating through the first encapsulant.

17. The manufacturing method of the semiconductor package according to claim 16, wherein the step of forming the through encapsulant via follows the step of detaching the first carrier, and precedes the step of removing the sacrificial pattern.

18. The manufacturing method of the semiconductor package according to claim 16, wherein the step of forming the through encapsulant via precedes the step of forming the first redistribution layer.

19. The manufacturing method of the semiconductor package according to claim 12, further comprising:
forming a plurality of electrical connectors at a side of the second redistribution layer facing away from the first redistribution layer.

20. The manufacturing method of the semiconductor package according to claim 12, wherein the sacrificial pattern comprises a photosensitive material.
